(19) United States
(12) Patent Application Publication
(10) Pub. No.: US 2024/0215458 A1
(43) Pub. Date: Jun. 27, 2024

(54) MEMORY DEVICE AND METHOD OF FORMING THE SAME

(71) Applicant: Yangtze Memory Technologies Co., Ltd., Wuhan (CN)

(72) Inventors: Yuxuan FANG, Wuhan (CN); Shan LI, Wuhan (CN); Dongxue ZHAO, Wuhan (CN); Lei LIU, Wuhan (CN); Zhiliang XIA, Wuhan (CN)

(21) Appl. No.: 18/089,838

(22) Filed: Dec. 28, 2022

(30) Foreign Application Priority Data
Dec. 22, 2022 (CN) 202211659427.3

(51) Int. Cl. H10N 50/10; H01L 23/528; H10B 61/00; H10N 50/01

(52) U.S. Cl. CPC H10N 50/10; H01L 23/5283; H10B 61/20; H10N 50/01

(57) ABSTRACT

A memory device includes a semiconductor layer and a stack structure over the semiconductor layer. The stack structure includes a cell array region and a staircase structure region. The cell array region includes multiple vertical levels of stacked transistor-magnetic tunnel junction (TMTJ) elements and a plurality of channel structures vertically extending through the stack structure. At least one channel structure includes a vertical core, a vertical magnetic reference layer, and a vertical tunnel barrier layer, which are shared by a set of magnetic tunnel junction (MTJ) elements associated with the at least one channel structure. The set of MTJ elements are located at different vertical levels of the stack structure.

### CROSS-REFERENCE TO RELATED APPLICATION

This application claims the priority of Chinese Patent Application No. 202211659427.3, filed on Dec. 22, 2022, the content of which is incorporated herein by reference in its entirety.

### FIELD OF THE DISCLOSURE

The present disclosure generally relates to the field of memory device and, more particularly, relates to memory device and formation method thereof.

### BACKGROUND

Spin-transfer torque magnetic random access memory (STT-MRAM) is a type of non-volatile data memory device that stores data using magnetoresistive cells, such as Magnetoresistive Tunnel Junction (MTJ) memory cells. Currently, memory cells or memory elements in an STT-MRAM array are generally in the two-dimensional (2D) configuration, that is, a plurality of individual memory cells (e.g., MTJ memory cells) are arranged in a 2D array. This limits the development of a higher density of memory cells in an STT-MRAM array.

### BRIEF SUMMARY OF THE DISCLOSURE

One aspect of the present disclosure provides a magnetic random access memory array. The magnetic random access memory array includes a semiconductor layer and a stack structure over the semiconductor layer. The stack structure includes a cell array region and a staircase structure region. The cell array region includes multiple vertical levels of stacked transistor-magnetic tunnel junction (TMTJ) elements and a plurality of channel structures vertically extending through the stack structure. At least one channel structure includes a vertical core, a vertical magnetic reference layer, and a vertical non-magnetic tunnel barrier layer, which are shared by a set of MTJ elements associated with the at least one channel structure. The set of MTJ elements are located at different vertical levels of the stack structure.

Another aspect of the present disclosure provides a method for forming a magnetic random access memory array. The method includes forming a vertical stack structure over a semiconductor layer. The stack structure includes a plurality of levels, and each level includes a plurality of vertically aligned horizontal layers. The method further includes forming at least one channel structure within the stack structure. Each of the at least one channel structure includes a vertical core, a vertical magnetic reference layer, and a vertical non-magnetic tunnel barrier layer. The method further includes, within each level, forming a vertical magnetic free layer coupled to each of the at least one channel structure, and forming a transistor adjacent to the vertical magnetic free layer. The vertical magnetic free layer, a portion of the vertical magnetic reference layer in the level, and a portion of the vertical non-magnetic tunnel barrier layer in the level together form a magnetic tunnel junction (MTJ) element. The MTJ element and the adjacent transistor together form a TMTJ element.

Other aspects of the present disclosure may be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1A illustrates an exemplary basic-level three-dimensional STT-MRAM device consistent with various disclosed embodiments in the present disclosure;

FIG. 1B illustrates a cross-sectional view (taken along plane A in FIG. 1A) of a cylindrical MTJ element consistent with various disclosed embodiments in the present disclosure;

FIG. 2 illustrates an exemplary stacked TMTJs (transistor-MTJ) for a 3D STT-MRAM device according to various embodiments of the present disclosure;

FIG. 3A illustrates an exemplary cylindrical MTJ with certain vertically aligned transistor components according to various embodiments of the present disclosure;

FIG. 3B illustrates an exemplary stacked cylindrical MTJs with certain vertically aligned transistor components according to various embodiments of the present disclosure;

FIG. 4A illustrates a side view of a cross-section of a portion of stacked TMTJs for a 3D STT-MRAM device according to various embodiments of the present disclosure;

FIG. 4B illustrates an aerial view of a cross-section of a portion of stacked TMTJs for a 3D STT-MRAM device according to various embodiments of the present disclosure;

FIG. 4C illustrates another side view of a cross-section of a portion of stacked TMTJs for a 3D STT-MRAM device according to various embodiments of the present disclosure;

FIG. 4D illustrates a side view of a cross-section of a staircase structure and a cell array region for a 3D STT-MRAM device according to various embodiments of the present disclosure; and

FIGS. 5A-5W illustrate various stages of forming a 3D STT-MRAM device consistent with various disclosed embodiments in the present disclosure.

### DETAILED DESCRIPTION

Reference will now be made in detail to exemplary embodiments of the present disclosure, which are illustrated in the accompanying drawings. Wherever possible, the same reference numbers will be used throughout the drawings to refer to the same or like parts.

Spin-transfer torque magnetic random access memory (STT-MRAM) is a type of non-volatile data memory device that stores data using magnetoresistive cells, such as Magnetoresistive Tunnel Junction (MTJ) memory cells. At the most basic level, an MTJ memory cell includes two magnetic layers that are separated by a thin, non-magnetic tunnel barrier layer. The first of the two magnetic layers, also referred to as a reference layer, has a magnetization that is fixed in a direction that is generally perpendicular to the plane of the layer (or in the plane of the layer). The second of the two magnetic layers, also referred to as a free layer, has a magnetization that is free to move so that it may be oriented in either of two directions that are both perpendicular to the plane of the magnetic free layer (or in the plane of the layer). Therefore, the magnetization of the magnetic free layer may be either parallel with the magnetization of the magnetic reference layer or anti-parallel with (or opposite to) the direction of the magnetic reference layer. The non-magnetic tunnel barrier layer is constructed of an insulating barrier material, such as Magnesium Oxide (MgO), Aluminum oxide (Al₂O₃), etc.

The electrical resistance through an MTJ memory cell in a direction perpendicular to the planes of the layers generally varies according to the relative orientations of the magnetizations of the magnetic reference layer and free layer, or more specifically, the orientation of the magnetization of the magnetic free layer at any time point since the magnetic reference layer is generally fixed. When the magnetization of the magnetic free layer is oriented in a same orientation as the magnetization of the magnetic reference layer, the electrical resistance through the MTJ memory cell is at its lowest electrical resistance state. On the contrary, when the magnetization of the magnetic free layer is in an orientation opposite to that of the magnetic reference layer, the electrical resistance is at its highest electrical resistance state. An MTJ memory cell may be switched between the low and high electrical resistance states, which can serve as a basis for use as a memory element for data storage. For instance, the low resistance state may be read as a “1” or one, whereas the high resistance state may be read as a “0” or zero.

Currently, the MTJ memory cells or memory elements in a memory cell array are generally in the two-dimensional (2D) configuration, that is, a plurality of individual MTJ memory cells are arranged in a 2D array. This limits the development of a higher density of memory cells in an STT-MRAM array.

The present disclosure provides a 3D memory device with stacked MTJ elements and a method of forming the 3D memory device. According to one embodiment, the 3D memory device includes a semiconductor layer and a stack structure over the semiconductor layer. The stack structure includes a cell array region and a staircase structure region. The cell array region includes multiple vertical levels of stacked transistor-magnetic tunnel junction (TMTJ) elements and a plurality of channel structures vertically extending through the stack structure. Each channel structure includes a vertically aligned cylindrical magnetic reference layer and a vertically aligned cylindrical non-magnetic tunnel barrier layer shared by a set of MTJ elements associated with the channel structure. Each of the set of MTJ elements located at different vertical levels of the stack structure has its own magnetic free layer and a horizontally aligned transistor coupled to the MTJ element.

In such a 3D memory device, a vertically aligned magnetic free layer within each level is adjacent to a non-magnetic tunnel barrier layer and a magnetic reference layer within a channel structure. The vertically aligned magnetic free layer when combined with the adjacent non-magnetic tunnel layer and magnetic reference layer form an MTJ element for data storage. The specific structure of such a 3D memory device is further described in detail below.

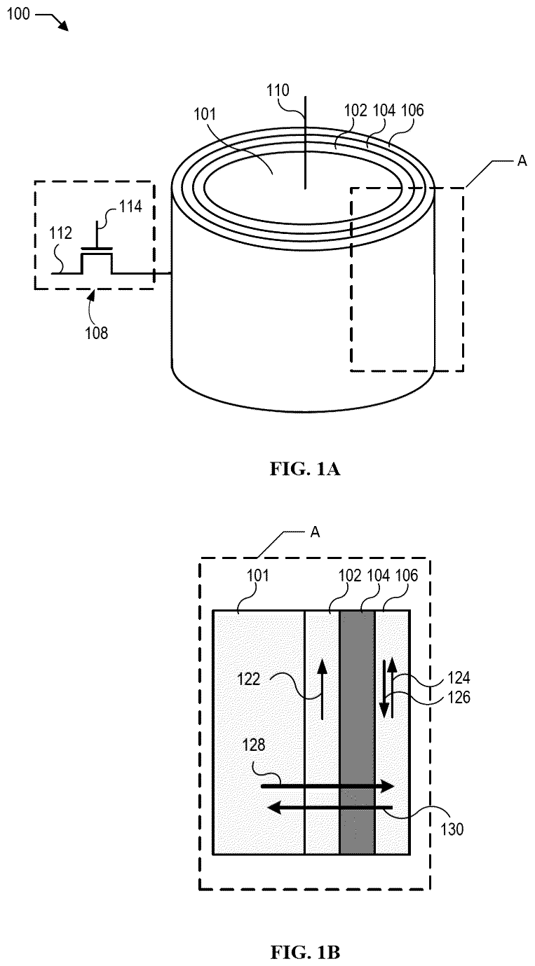

FIG. 1A illustrates an exemplary basic-level three-dimensional STT-MRAM device 100, according to some embodiments. As illustrated, at the basic level, the STT-MRAM device 100 includes a single vertically aligned MTJ element with a magnetic reference layer 102, a non-magnetic tunnel barrier layer 104, and a magnetic free layer 106, and an access transistor (also referred to as “select transistor” in some embodiments) 108 coupled to the MTJ element. The magnetic reference layer 102, non-magnetic tunnel barrier layer 104, and magnetic free layer 106 wrap around a central core 101, thereby forming a three-dimensional cylindrical (or conical) MTJ element. The magnetic reference layer 102 (also referred to as “a first cylindrical ferromagnetic layer” in some embodiments) surrounds the core 101, the non-magnetic tunnel barrier layer 104 surrounds the magnetic reference layer 102, and the magnetic free layer 106 (also referred to as “a second cylindrical ferromagnetic layer” in some embodiments) surrounds the non-magnetic tunnel barrier layer 104. Collectively, the core 101 and the three layers 102, 104, and 106 form an MTJ element for non-volatile data storage.

In some embodiments, each of the magnetic reference layer 102, non-magnetic tunnel barrier layer 104, and magnetic free layer 106, when wrapped around the central core 101, is a hollow cylinder (e.g., a cylindrical shell). In some embodiments, each of the magnetic reference layer 102, non-magnetic tunnel barrier layer 104, and magnetic free layer 106, when wrapped around the central core 101, is a conical shell instead a hollow cylinder.

In some embodiments, the core 101, the magnetic reference layer 102, the non-magnetic tunnel barrier layer 104, and the magnetic free layer 106 are coaxial (e.g., concentric) with one another. Additionally, in some embodiments, heights of the core 101 and the three layers 102, 104, and 106 substantially match one another (e.g., the core 101 and the three layers 102, 104, and 106 are coplanar with one another at a first end of the MTJ element). In some embodiments, heights of the core 101 and the three layers 102, 104, and 106 substantially are not equal (e.g., the core 101 and the three layers 102, 104, and 106 are not coplanar with one another at a second end of the MTJ element, as will be described later).

In some embodiments, each of the cylindrical magnetic reference and free layers is composed of identical, or varying, material(s) and/or thickness(es). For example, each of the cylindrical magnetic layers can be made of CoFeB with various compositions and each has a thickness ranging from 0.5 to 10 nm. In some embodiments, the boron (B) component for the first and/or second cylindrical magnetic layers varies between 10% and 40%. In some embodiments, the composition of the magnetic reference layer 102 differs from the composition of the magnetic free layer 106. For example, the magnetic reference layer 102 may include at least one material (e.g., Tantalum and/or Tungsten) not included in the magnetic free layer 106. In some embodiments, the magnetic reference layer 102/free layer 106 includes multiple sublayers making the magnetic reference layer 102/free layer 106 more thermally stable. It should be noted the magnetic reference and free layers may have other thickness(es) and/or material(s).

The non-magnetic tunnel barrier layer 104 can be made from MgO, Al₂O₃, or the like. However, in some embodiments, the non-magnetic tunnel barrier layer 104 can be made from Mg₁₋ₓAl₂₋ₓO₄. In some embodiments, the materials used for different layers in the STT-MRAM device 100 are stable at various processing temperatures in the fabrication process of forming the device 100.

In some embodiments, the core 101 is disposed along a vertical axis and is used to provide structural support for the STT-MRAM device 100. In some embodiments, the core 101 is made from a metal (e.g., a non-magnetic metal) and serves as a current lead (e.g., serving as a bit line for the MTJs along the core) for the STT-MRAM device 100. In some embodiments, the core 101 is made from, at least partially, one or more of Tantalum (Ta), Tungsten (W), Copper (Cu), Ruthenium (Ru), and Niobium (Nb), or a combination thereof. In some embodiments, the core 101 includes multiple sublayers, among which one sublayer may serve as a current lead, and another layer mainly provides structural support. In one example, the cored 101 may include a bit line sublayer (not shown) adjacent to the magnetic reference layer 102. In another example, the core 101 itself may be a bit line layer. The bit line sublayer/bit line layer (together or individually referred to as “a bit line layer”) is connected to a bit line 110 of the STT-MRAM device 100.

In some embodiments, the core 101 is conical (or elliptical) in shape. Alternatively, in some embodiments, the core 101 is cylindrical, rectangular, square, or in any other proper shape. It is to be noted that the shape of the magnetic reference layer 102, non-magnetic tunnel barrier layer 104, and magnetic free layer 106 conform to an outer surface of the core 101. Thus, when the core 101 is conical in shape, the magnetic reference layer 102, non-magnetic tunnel barrier layer 104, and magnetic free layer 106 are also conical in shape.

In some embodiments, the basic level STT-MRAM device 100 is also coupled to a source line or plate line 112 via a transistor 108, which is operated by a word line 114. In some embodiments, the source line/plate line 112 is connected to the magnetic free layer 106 (e.g., via the drain of the transistor) and the bit line 110 is connected to the core 101. In some embodiments, the transistor 108 and the associated plate line/source line and word line can form a layered structure, as will be described later. In some embodiments, the STT-MRAM device 100 receives a current from the plate line/source line 112 or from bit line 110. In some embodiments, the received current may cause a change in the magnetization orientation of the magnetic free layer, and thus the resistance state of the MTJ element, resulting in a read/write operation of the STT-MRAM device 100.

FIG. 1B illustrates a cross-sectional view (taken along plane A in FIG. 1A) of the cylindrical MTJ element according to some embodiments. For ease of illustration and discussion, a width of each layer 102, 104, and 106 shown in FIG. 1B is the same. However, in some embodiments, the width of one or more layers 102-106 may differ, depending on the configurations. For example, in some embodiments, the width of the magnetic reference layer 102 is greater than the width of the magnetic free layer 106, to increase the thermal stability (e.g., the energy barrier) of the magnetic reference layer 102.

As also shown in FIG. 1B, in some embodiments, the cylindrical MTJ element has an in-plane magnetization orientation. In the cross-sectional view shown in FIG. 1B, the fixed magnetization direction 122 for the magnetic reference layer 102 is chosen to be in an upward direction and is represented by an up arrow. In some embodiments (not shown), the fixed magnetization direction of the magnetic reference layer 102 is in a downward direction (e.g., a down arrow).

In FIG. 1B, when the cylindrical MTJ element is in the parallel configuration, the magnetization direction 124 of the magnetic free layer 106 is the same as the magnetization direction 122 of the magnetic reference layer 102. The parallel configuration sometimes is also referred to as a “low (electrical) resistance” state. In the illustrated embodiment, the magnetization direction 122 of the magnetic reference layer 102 and the magnetization direction 124 of the magnetic free layer 106 are both in the upward direction in the low resistance state. As described earlier, the magnetization direction of the magnetic free layer 106 relative to the magnetic reference layer 102 changes the electrical resistance of the cylindrical MTJ element. Accordingly, under certain circumstances (e.g., when a current is applied to the MTJ element), the cylindrical MTJ element is switched to the anti-parallel configuration. In the anti-parallel configuration, the magnetization direction 126 of the magnetic free layer 106 is opposite to the “fixed” magnetization direction 122 of the magnetic reference layer 102. The anti-parallel configuration is sometimes also referred to as a “high (electrical) resistance” state.

In some embodiments, by changing the magnetization direction of the magnetic free layer 106 relative to that of the magnetic reference layer 102, the resistance states of the MTJ element can be varied between low resistance to high resistance, enabling digital signals corresponding to bits of “0” and “1” to be stored and read. In some embodiments, the parallel configuration (low resistance state) corresponds to a bit “0,” whereas the anti-parallel configuration (high resistance state) corresponds to a bit “1.”

In some embodiments, in order to change the cylindrical MTJ element from a parallel configuration to an anti-parallel configuration (or vice versa), a current (e.g., electrons) is applied to the cylindrical element. In some embodiments, to change the cylindrical MTJ element from a parallel configuration to an anti-parallel configuration, a current is applied through the plate line/source line 112 (e.g., via the transistor 108). In those embodiments, the received current (e.g., electron flow 130) flows radially from the plate line/source line 112 through the magnetic free layer 106 and the tunnel barrier layer 104 toward the magnetic reference layer 102, and the current 130 imparts a torque on magnetization of the magnetic free layer 106. When a sufficiently large current is applied (e.g., a sufficient number of polarized electrons flow into the magnetic free layer 106), the spin torque flips, or switches, the magnetization direction (or orientation) of the magnetic free layer 106 from the magnetization direction 124 to the magnetization direction 126. As a result of the switching, the MTJ element transitions from a parallel configuration to an anti-parallel configuration. In some embodiments, to change the cylindrical MTJ element from an anti-parallel configuration to a parallel configuration, a current is applied through the core 101. The current flows through the magnetic reference layer 102 through the cylindrical structure towards the magnetic free layer 106. When a sufficiently large current is applied, the spin torque flips, or switches, the magnetization direction of the magnetic free layer 106 from the magnetization direction 126 to the magnetization direction 124.

In some embodiments, a current is applied through the core 101 when the MTJ element is in the parallel configuration, and the current is applied through the magnetic free layer 106 when the MTJ element is in the anti-parallel configuration. From the above, it can be seen that switching configurations are performed by reversing the flow of the current. Switching from the parallel configuration to the anti-parallel configuration utilizes current in one polarity (direction) and switching from the anti-parallel configuration back to the parallel configuration utilizes current in the opposite polarity.

FIGS. 1A-1B illustrate an exemplary structure and operation of an STT-MRAM device 100 with a single MTJ element and a single transistor (also referred to as “TMTJ”). In some embodiments, multiple TMTJs as illustrated in FIG. 1A can be horizontally aligned and vertically stacked one over another to form a 3D STT-MRAM structure, as will be described in detail below.

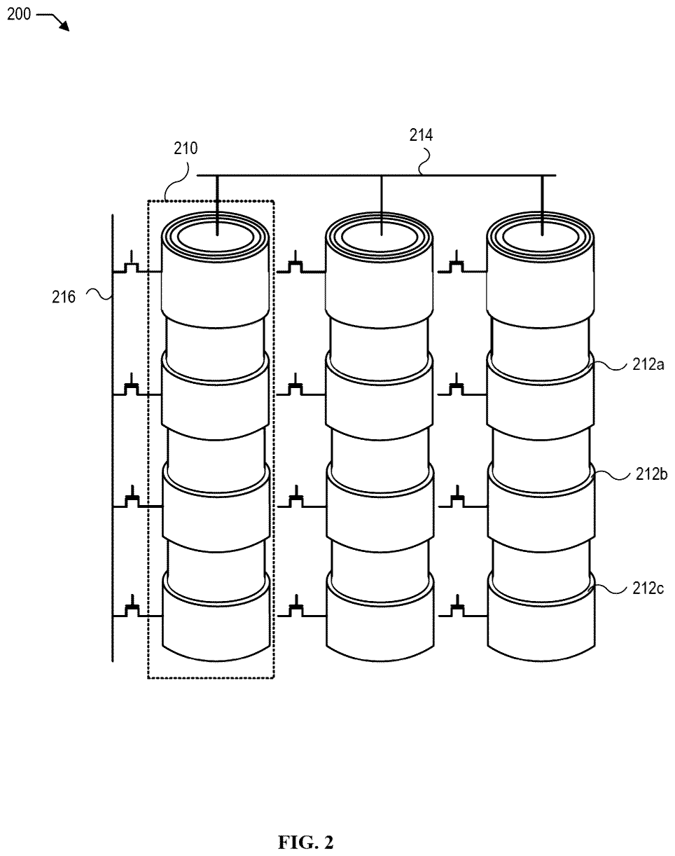

FIG. 2 illustrates an exemplary stacked 3D STT-MRAM device 200, according to some embodiments. While only one row of stacked TMTJs with a limited number of TMTJs (vertically aligned in four levels with each level including three MTJs) are illustrated in FIG. 2, it is to be noted that there can be any number of rows of stacked TMTJs, any number of TMTJs in each row, and any levels of stacked TMTJs in a stacked 3D STT-MRAM device 200.

In some embodiments, for the MTJs stacked over one another in a same column (e.g., MTJs in column 210), these MTJs may have certain shared structures that vertically align and extend across all MTJs in the same column. For example, as illustrated in FIG. 2, the MTJs in the same column have a shared core, magnetic reference layer, and non-magnetic tunnel barrier layer. These shared core, magnetic reference layer, and non-magnetic tunnel barrier layer can extend across all MTJs in the same column (e.g., column 210). While not shown, the shared core may itself be a bit line layer, or the core further includes a bit line sublayer, either of which is also shared among the MTJs in the same column. By using the shared structures among multiple MTJs, it makes the manufacturing process less complex and easier to control, and can allow a high dense MTJs to be fabricated in an STT-MRAM device.

As also illustrated in FIG. 2, the magnetic free layer in each MTJ is not shared with other MTJs in the same column. That is, each MTJ has its own magnetic free layer (e.g., magnetic free layer 212a, 212b, or 212c in FIG. 2) that is separated from adjacent MTJs, either vertically or horizontally. In some embodiments, a dielectric material/layer may be added between TMTJs between different levels and between different rows and columns, and thus separate the magnetic free layers from one another. Accordingly, the switching of magnetization direction in the magnetic free layer in each MTJ is independent of other MTJs in 3D STT-MRAM device 200, allowing each MTJ in the device 200 to operate as an independent memory cell. In some embodiments, a row of independent MTJs are connected to a bit line 214, through the cores, and a column of independent MTJs are connected to a source line or plate line 216 to form a 3D memory array.

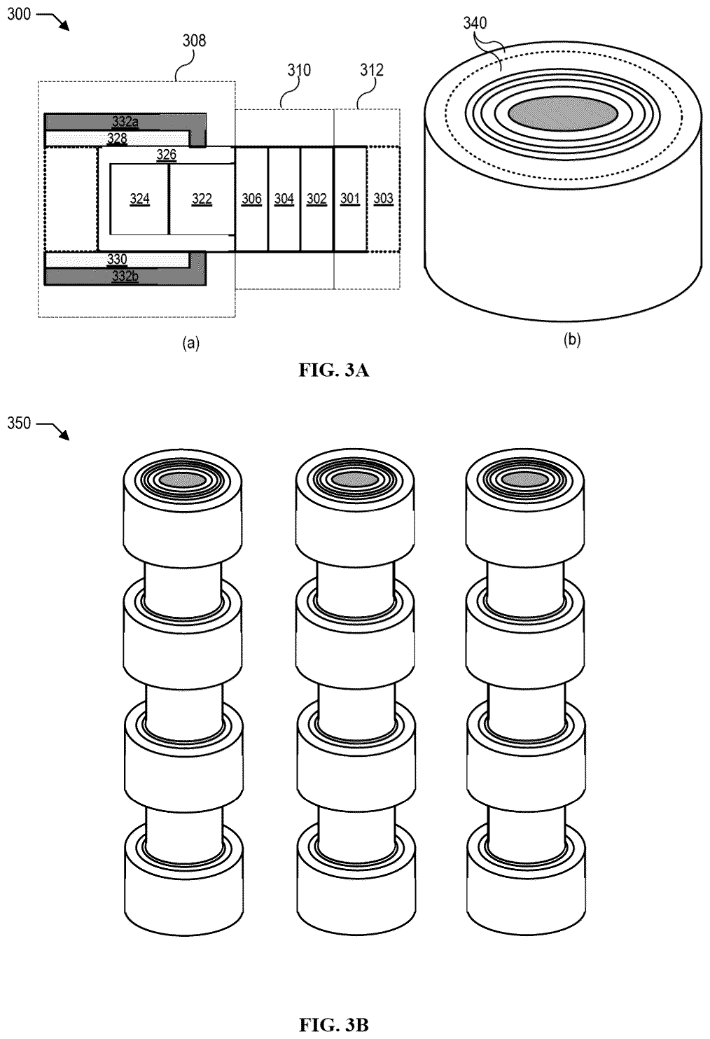

In some embodiments, each MTJ also has its coupled transistor that is also independent of other transistors. That is, each transistor is independently connected with its respective MTJ, but not other MTJs in the 3D STT-MRAM device 200. In some embodiments, the array of transistors organized along the array of MTJs can be formed as a layered and/or stacked structure, as further described in FIG. 3A-3B.

FIG. 3A illustrates an exemplary TMTJ with a portion of a transistor vertically aligned with a coupled MTJ, according to some embodiments. Specifically, Part (a) of FIG. 3A illustrates a schematic diagram of a TMTJ, and Part (b) of FIG. 3A illustrates a TMTJ with a portion of a transistor vertically aligned with the coupled MTJ. As illustrated in Part (a), a TMTJ unit includes a transistor 308, an MTJ element 310, and a core structure 312. The core structure 312 includes a bit line layer 301 and optionally a support structure 303. The MTJ element 310 includes a magnetic reference layer 302 next to the bit line layer 301, a non-magnetic tunnel barrier layer 304 next to the magnetic reference layer 302, and a magnetic free layer 306 next to the non-magnetic tunnel barrier layer 304. The access transistor 308 may include a gate structure (e.g., a dual gate structure including a polysilicon gate 322 and/or a metal gate 324) and an insulation layer (e.g., a high k insulator 326) separating the gate structure from other parts of the transistor 308. The dual gate structure may include a control gate and a floating gate. As illustrated, the transistor 308 further includes a source 328 and a drain 330, and two separate word lines 332a and 332b coupled to the gate structure from the top and bottom of the gate structure.

As further illustrated in Part (b) of FIG. 3A, in some embodiments, certain components (e.g., dual gate structure including the polysilicon gate 322 and metal gate 324) included in a transistor 308 can be configured in a vertically aligned form that surrounds a vertically aligned MTJ element 310. For instance, as illustrated in Part (b) of FIG. 3A, there may be multiple vertically aligned layers 340 that each correspond to one or more components of the transistor 308. These vertically aligned layers 340 surround an inner MTJ element. Depending on the number and types of components included in transistor 308, the number and/or layers of transistor components included in the layered portion 340 can vary. Additionally, for each layer included in the layered portion 340, it may have different heights and thicknesses, and can be made of different materials. In some embodiments, for each layered component included in the layered portion 340, there may be an additional component(s) coupled to a layered component from the top or bottom of the layer structure (e.g., word lines 332a and 332b coupled to the layered gate component 324 and 326 from the top and bottom of the layered portion 340).

In some embodiments, certain transistor components are not included in the layered portion 340, but rather can be formed in other forms. For example, certain components included in a transistor 308 can be a lateral layer that extends along a lateral plane perpendicular to the vertically aligned layered portion 340. For example, high K insulator 326, source 328, drain 330, and word line 332a/332b of the transistor 308 may be instead a lateral layer that extends along a lateral direction and is stacked with other lateral layers.

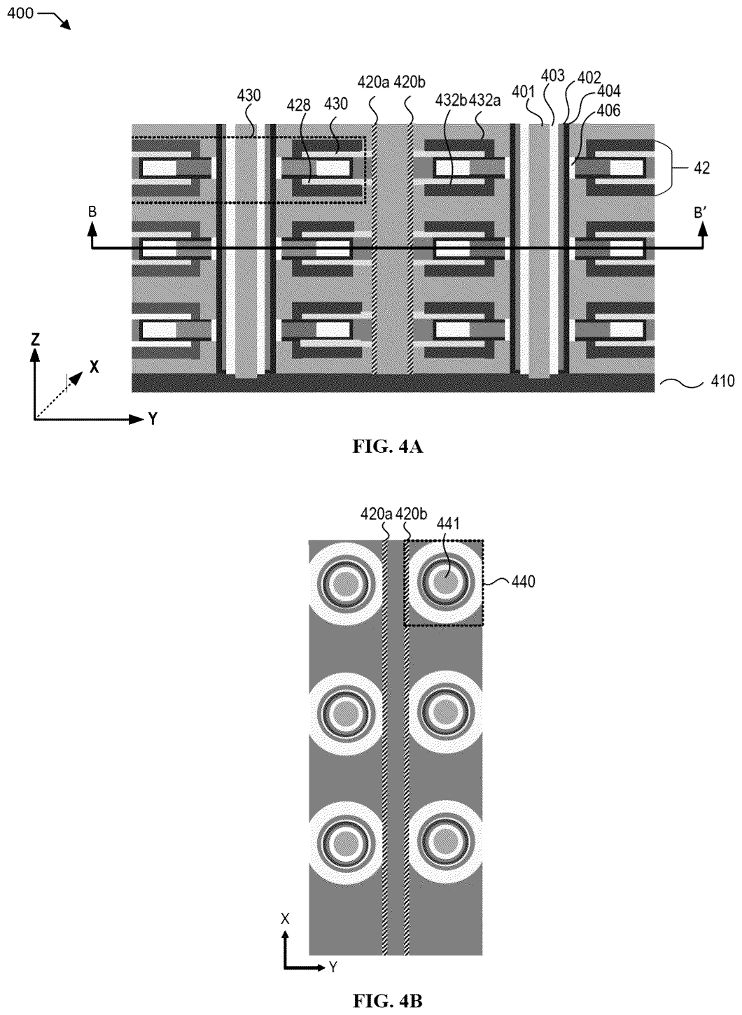

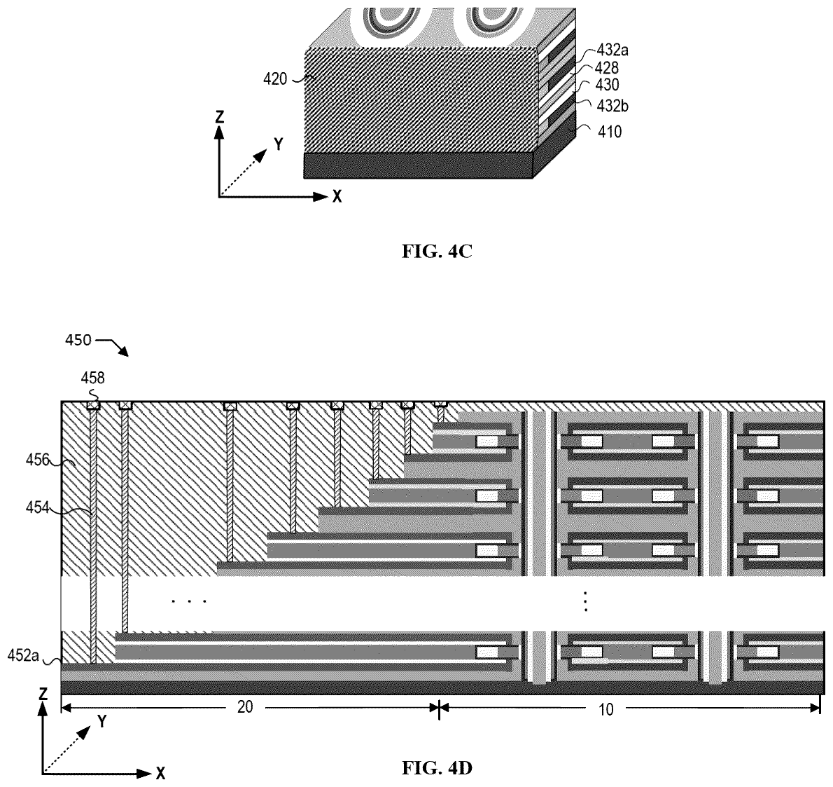

FIG. 3B illustrates vertically aligned portions of an exemplary 3D STT-MRAM device 350, according to some embodiments. As illustrated, each vertically aligned portion of a TMTJ (with certain portions or components not shown) includes a core, an MTJ element, and certain layered components for a coupled transistor. The TMTJs in a same column share a same core, magnetic reference layer, and non-magnetic tunnel barrier layer but have independent free layers and transistor components. Similar to device 200 shown in FIG. 2, the 3D STT-MRAM device 350 can also have a different number of rows and levels of stacked TMTJs. In addition, the exemplary 3D STT-MRAM device 350 also includes a dielectric material (not shown) that separates TMTJs from one another and components within each TMTJ, as further described below in FIG. 4A.

FIG. 4A illustrates a cross-section view of a portion of a 3D STT-MRAM device 400 with stacked TMTJs, according to some embodiments. As illustrated, the 3D STT-MRAM device 400 includes a substrate 410 and multiple levels of stacked TMTJs 42 over the substrate 410. In each level, there are multiple TMTJs organized in a 2D array. The TMTJs in a same column share a core 401, a bit line layer 403, a magnetic reference layer 402 and a non-magnetic tunnel barrier layer 404. Each TMTJ has its own magnetic free layer 406 and a transistor coupled to the magnetic free layer 406. Depending on the configurations, a coupled transistor may have different components. According to one example, the transistor may include a metal gate and/or polysilicon gate, a source, a drain, a high-k insulator, and word lines as illustrated in FIG. 3A. In some embodiments, the transistor may also have different components than those illustrated in FIG. 3A. In addition, in some embodiments, MTJ components included in an MTJ are not limited to the magnetic reference and free layers and non-magnetic tunnel barrier layer, but rather can have additional layers, such as Synthetic Anti-Ferromagnet (SAF) layer, capping layer, and so on.

It is to be noted that since the main components of each TMTJ are vertically aligned and have a shape of a circle, an ellipse, a rectangular, or the like, the two portions on the left and right side of a core 401 are actually two different parts of a same TMTJ. For instance, the box 430 in FIG. 4A represents a single TMTJ, which corresponds to a single unit 440 shown in FIG. 4B, which has a left and right portion around a center core 441.

In some embodiments, a set of TMTJs in a same column also have a shared plate line for connecting to the source of each transistor. For example, as shown in FIG. 4A, there is one source line or plate line 420a connected to a first set of transistors (e.g., the set of transistors on the left of the plate line 420a in FIG. 4A) and another source line or plate line 420b connected to a second set of transistors (e.g., the set of transistors on the right of the plate line 420b in FIG. 4A). In some embodiments, the source lines or plate lines 420a and 420b may be a vertical plate that continuously or discretely extends along a lateral direction (e.g., along a first direction corresponding to the X axis in FIG. 4A). In some embodiments, there are certain insulation materials between the adjacent plate lines.

FIG. 4B illustrates a cross-section view of a portion of the 3D STT-MRAM device 400 along a line BB′ illustrated in FIG. 4A. As can be seen, the two plate lines 420a and 420b are actually two plates that vertically extend along the Z axis and laterally extend along the X axis. The source of each transistor may extend along a second lateral direction (e.g., along the Y axis as illustrated in FIG. 4A) to connect to a corresponding plate line 420.

In some embodiments, as illustrated in FIG. 4A, the upper and lower word lines (e.g., word lines 432a and 432b in FIG. 4A) included in a transistor do not extend along the Y axis and do not connect with a plate line 420a or 420b. Instead, these word lines extend along the X axis until reaching a staircase region, as will be described later.

FIG. 4C illustrates a 3D view of a portion of the 3D STT-MRAM device 400, according to some embodiments. As can be seen, the source line layer 428 of the transistor extends along the Y axis and is connected to a plate line 420, which is a plate that extends along the X axis. The upper and lower word lines 432a and 432b do not extend along the Y axis to connect to the plate line 420. Instead, the upper and lower word lines 432a/432b extend along the X axis and reach a staircase structure region for connecting to contact plugs formed in that region, as will be described below. While the drain layer 430 is illustrated as being connected to the plate line, in some embodiments, the drain layer 430 is not connected to the plate line 420. Instead, there is an insulation material between the plate line 420 and the drain layer 430. The drain 430 may be actually connected to the magnetic free layer of the coupled MTJ in the TMTJ element.

FIG. 4D illustrates a cross-section of an exemplary 3D STT-MRAM device 450 with a staircase region, according to some embodiments. As illustrated, the 3D STT-MRAM device 450 includes a substrate and multiple levels of stacked TMTJs formed over the substrate to form a stack structure over the substrate. The stack structure includes a TMTJ cell array structure formed in a cell array region 10 and a staircase structure formed in a staircase structure (SS) region 20. The cell array region 10 may include a plurality of stacked TMTJs with respective word lines extending into the staircase structure region 20. The word lines in the different levels have different stair lengths along a lateral direction (e.g., along the X axis) of the substrate. For example, as shown in FIG. 4D, the word line 452a closest to the substrate has the greatest stair length among all of the plurality word lines in the staircase structure region 20.

It is to be noted that since each level of TMTJs include two layers of word lines (or two word line layers), each of the two word line layers may have a different stair length. For example, the lower word line layer has a greater stair length than the upper word line layer in the same level. In addition, the two word line layers may also have different functional units/structures under each word line layer. For example, for an upper word line layer, it may include a source line layer, an insulation layer, and a drain layer that have a same stair length as the upper word line layer. For a lower word line layer in each level, it may include only an insulation layer that has a same stair length as the lower word line layer.

In some embodiments, a dielectric layer 456 may be also formed over the substrate in the staircase structure region 20. In some embodiments, the stack structure over the substrate may further include word line contact plugs 454 formed in the staircase structure region 20. The word line contact plugs 454 may extend vertically within the dielectric layer 456. Each word line contact plug 454 may have an end (e.g., a lower end) in contact with a corresponding word line layer in the staircase structure region 20, to individually address the corresponding word line of the associated MTJ(s).

In some embodiments, each word line contact plug 454 contacts a corresponding word line in the staircase structure region 20 on a side away from the substrate along a vertical direction. The word line contact plugs 454 may include a conductive material formed by filling contact holes and/or contact trenches formed through an etching process. In one embodiment, the conductive material may be W. In some embodiments, filling the contact holes and/or contact trenches may include depositing a barrier layer, an adhesion layer, and/or a seed layer before depositing the conductive material. In some embodiments, each word line contact plug 454 may further include a contact pad 458.

It is to be noted that, while only one staircase structure region 20 is illustrated in FIG. 4D, in some embodiments, the stack structure may include more than one staircase structure region 20. For example, there may be another staircase structure region 20 on the right side of the cell array region 10 illustrated in FIG. 4D. In some embodiments, a 3D STT-MRAM device 450 may include additional components not shown in FIGS. 4A-4C. For example, while not illustrated, there are certain row decoders and/or word line drivers, function control unit(s), reference voltage generator(s), write driver(s), etc., that may be connected to the bit line, plate line, or word lines of the 3D STT MRAM devices.

From the above various embodiments described in FIGS. 1A-4C, it can be seen that in the disclosed embodiments, the MTJ memory units are stacked and vertically aligned with certain structures shared among a large number of MTJ units. This effectively increases the memory cell dense of a cell array containing MTJ memory elements. In addition, by sharing certain components among a number of MTJ elements, it simplifies the manufacturing process and alignment of a large number of MTJ elements in a 3D cell array.

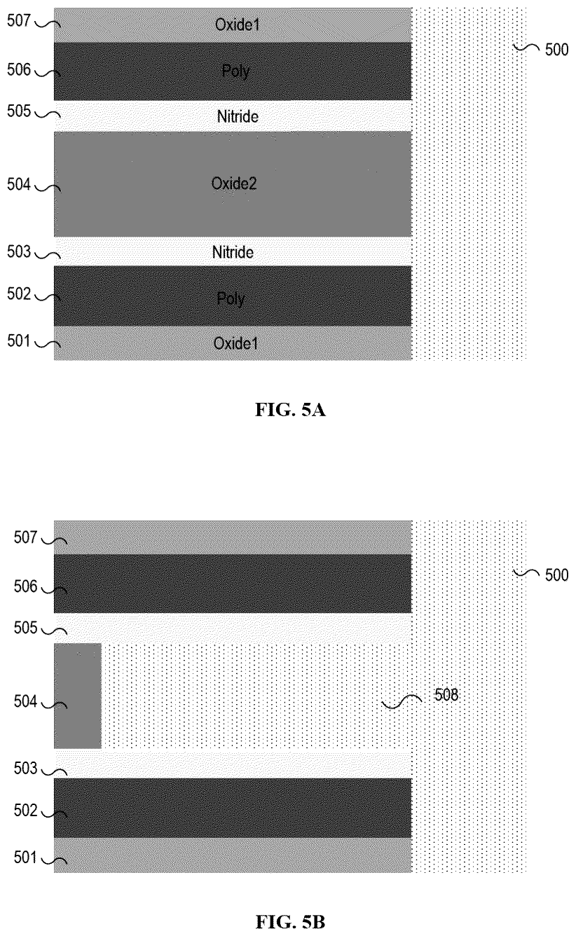

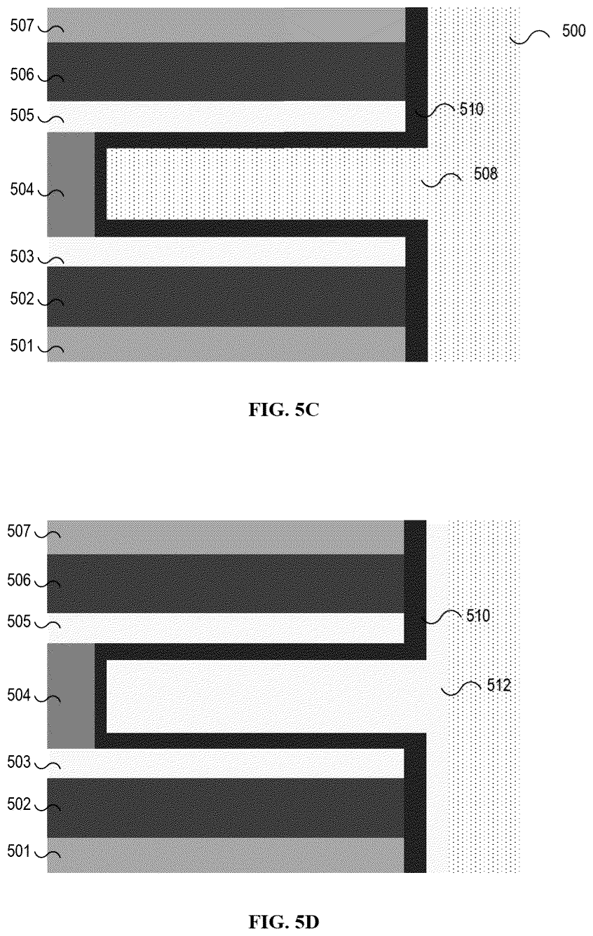

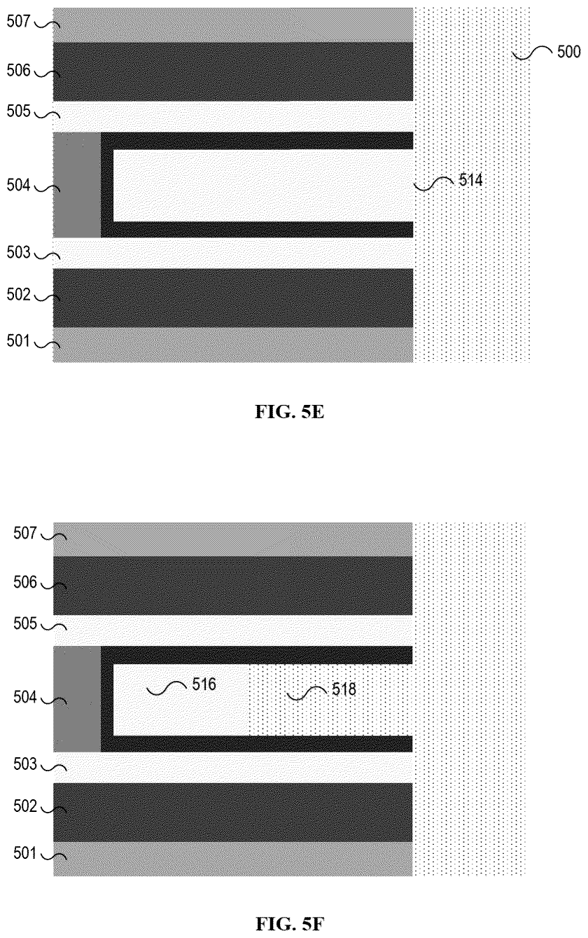

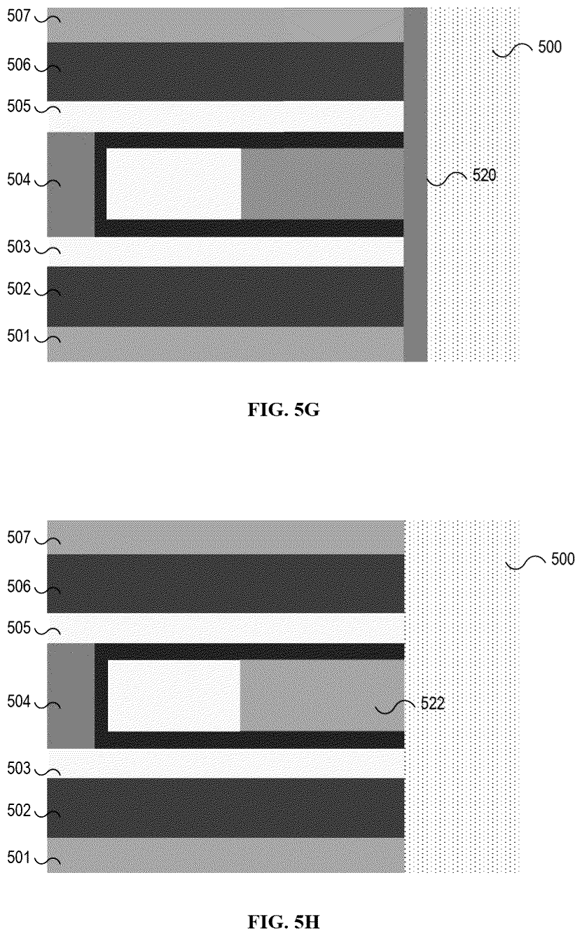

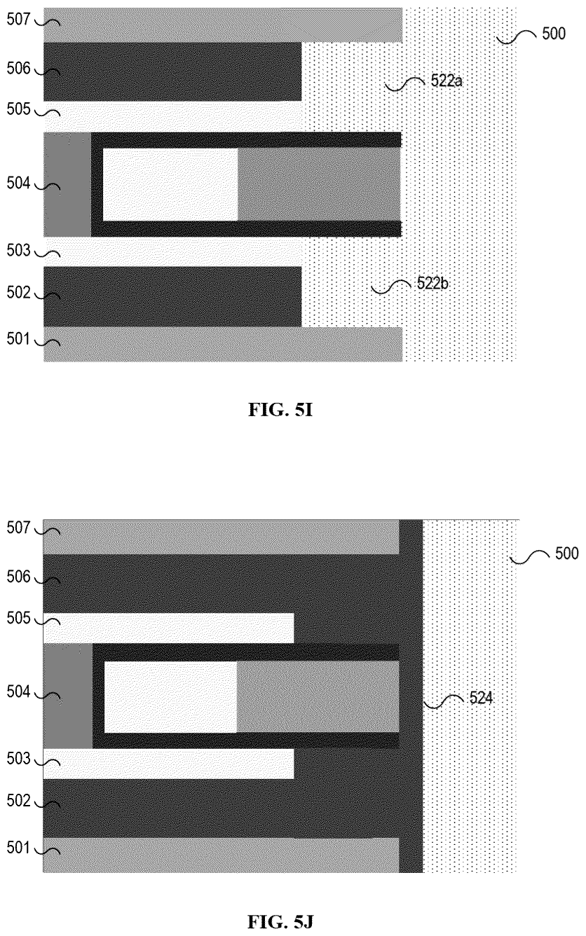

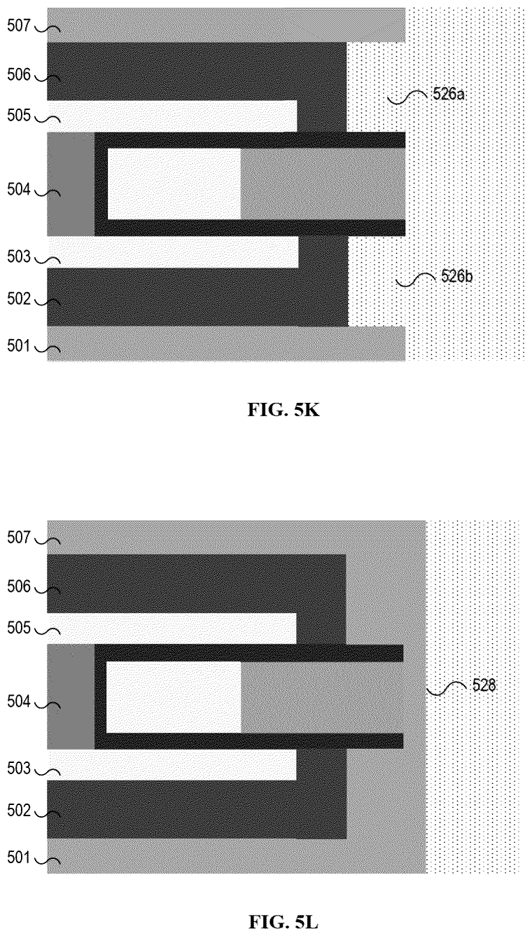

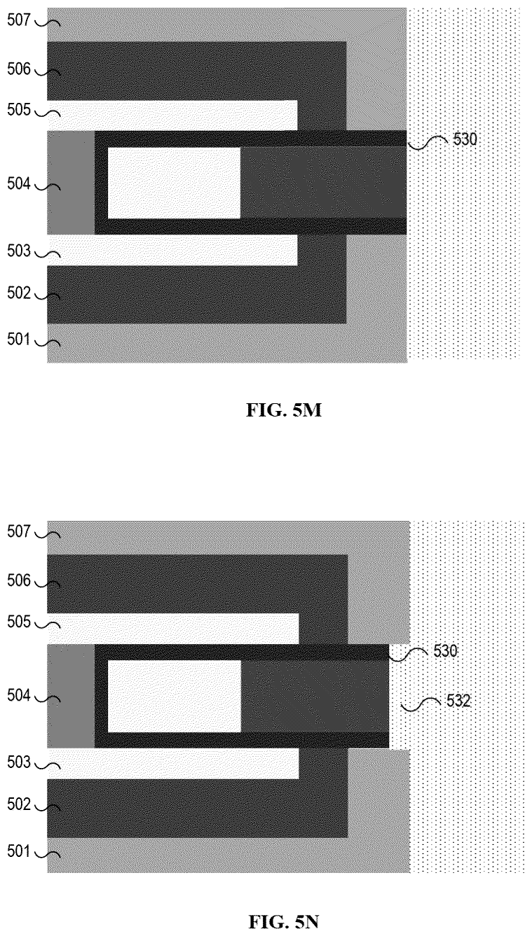

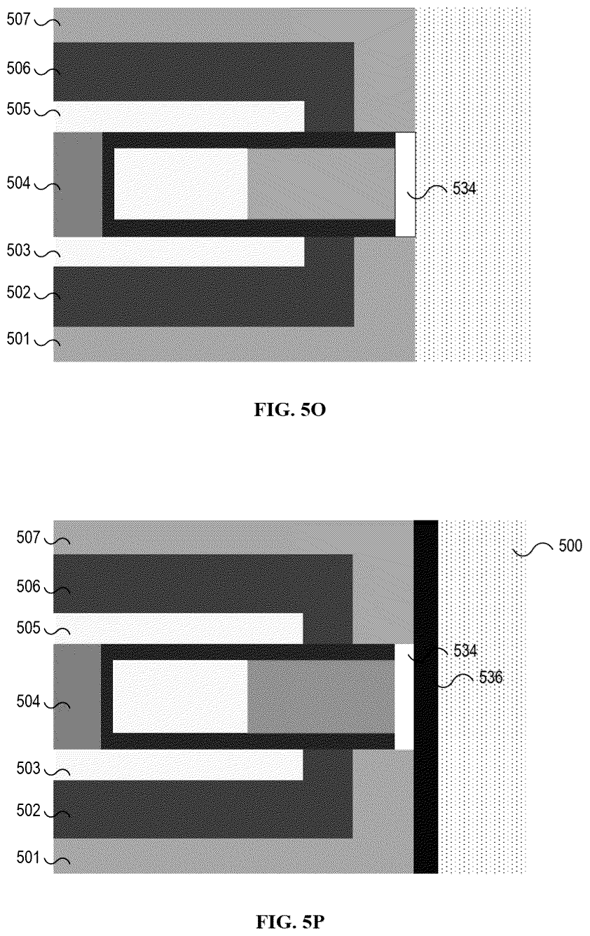

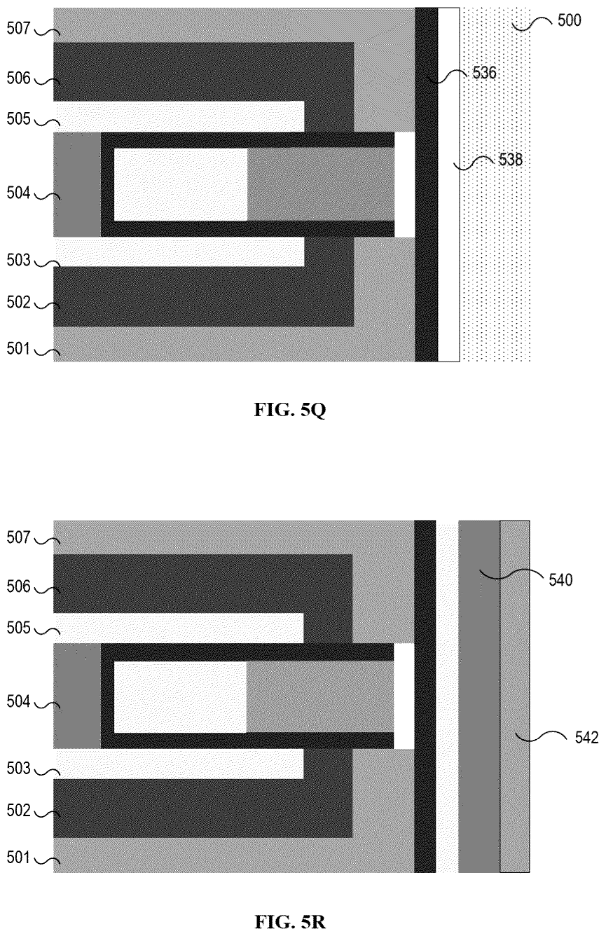

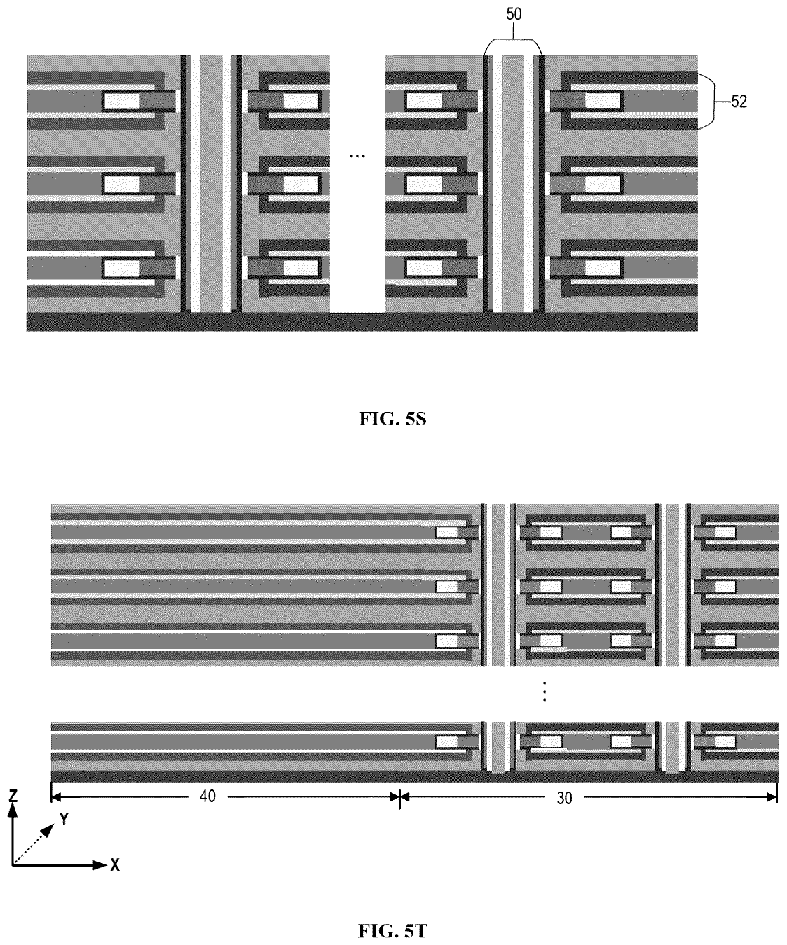

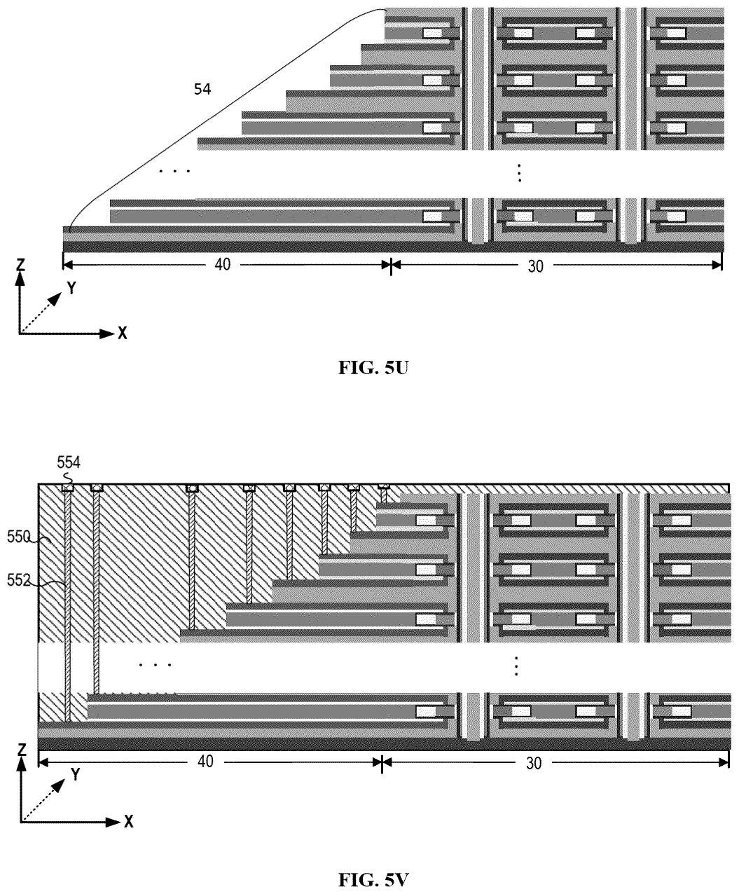

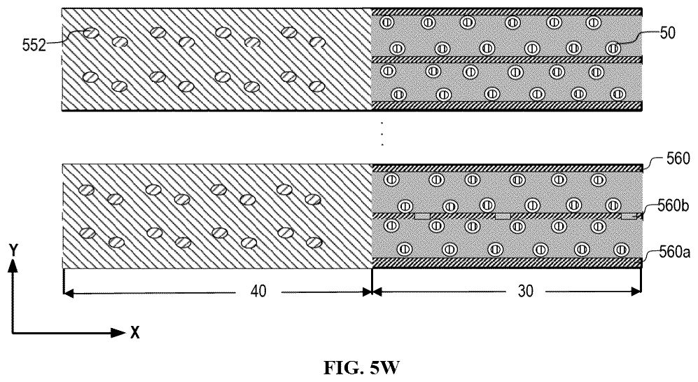

Various embodiments of the present disclosure further provide a method for forming 3D STT-MRAM devices described above. Referring to FIG. 5A, at first, a multilayer stack structure containing seven different horizontal layers 501-507 is formed over a substrate (not shown). The seven layers are vertically aligned and may include a first dielectric layer 501, a first conductor layer 502, a second dielectric layer 503, a third dielectric layer 504, a fourth dielectric layer 505, a second conductor layer 506, and a fifth conductor layer 506. According to one embodiment, the seven layers may be a composition of O/P/N/O/N/P/O layers, as illustrated in FIG. 5A. Here O represents an oxide layer, which can be a silicon oxide and/or silicon oxynitride layer, P represents a polysilicon layer, and N represents a nitride layer. A surface of the substrate may include a combination of dielectric materials, e.g., silicon oxide or low-K dielectric material, and metal features like interconnect structures and/or electrodes. Each of the O/P/N/O/N/P/O layers is sequentially deposited as a thin film using pulsed laser deposition, chemical vapor deposition, atomic layer deposition, sputtering, or other suitable deposition techniques. It is to be noted that, in some embodiments, each of the layers 501-507 may be replaced with other materials with similar functions/properties. For example, in some embodiments, one of the oxide layers 501, 504, and 507 may be replaced with another non-oxide dielectric layer, a polysilicon word line layer may be replaced with a metal layer, etc.

In some embodiments, one level of multilayer stack structure (also referred to as ((O/P/N/O/N/P/O)₁) allows forming one level of 2D TMTJ cell array. To allow to form a stacked TMTJ 3D memory cell array, multiple repeats of multilayer stack structures (O/P/N/O/N/P/O)₁ can be then deposited one after another, to form a stack structure containing n levels of multilayer stack structure (also referred to as (O/P/N/O/N/P/O)ₙ) (not shown). In the following, the specific processes are illustrated with reference to the formation of a single TMTJ element. However, it is to be noted that the processes can be simultaneously applied to form multiple TMTJ elements at a same and different vertical levels.

In some embodiments, to allow access inside the multilayer stack structure of (O/P/N/O/N/P/O)₁ at different levels to form transistors and MTJs at each level, a plurality of channel holes may be first formed through an etching process. Each channel hole may reach the substrate and may have a shape and size that match the shape and size of the shared non-magnetic tunnel barrier layer among the plurality of MTJs in a same column. FIG. 5A illustrates a channel hole 500 for accessing inside the multilayer stack structure of (O/P/N/O/N/P/O)₁ at different levels. It is to be noted that while only one level is illustrated in FIG. 5A, the channel hole 500 may actually access all levels of the stack structure formed on the substrate. In addition, while only (O/P/N/O/N/P/O)₁ at one side of the channel hole 500 is illustrated, the channel hole 500 may actually access (O/P/N/O/N/P/O)₁ at any side of the channel hole, thereby forming a cylindrical structure or the like. Accordingly, while only processing in one (O/P/N/O/N/P/O)₁ from one side is illustrated hereinafter, it is to be noted that a similar process can be simultaneously applied to (O/P/N/O/N/P/O)₁ at any level and from any side, thereby allowing a whole 3D STT MRAM cell array to be formed in the following process.

It is to be noted that while there are three oxide layers, these three oxide layers may be formed using different materials. For example, the oxide2 layer 504 and oxide1 layer 501 and oxide1 layer 507 may be formed using different materials, which then allows a selective etching of one oxide layer (e.g., oxide layer 504) without necessary etching of another oxide layer (e.g., oxide1 layer 501 or oxide1 layer 507). In addition, while each level of (O/P/N/O/N/P/O)₁ in the stack structure includes seven layers, in some embodiments, the bottom layer O and the top layer O within (O/P/N/O/N/P/O)₁ may serve the same functions, and thus the same material may be used during a fabrication process. Accordingly, in the manufacturing process, only six layers (e.g., (O/P/N/O/N/P)₁ or (P/N/O/N/P/O)₁) may be deposited in each repeat, except the bottom level or top level, which may include an additional layer of O in the fabrication process.

It is also to be noted that the channel holes may be not evenly distributed across all the areas of the formed stack structure. Instead, these channel holes are formed according to a predefined pattern. For example, these channel holes may be formed only in the cell array region, but not in the staircase structure region of an in-fabrication STT-MRAM device. In addition, the formed channel holes may be patterned based on the to-be-formed plate lines inside the in-fabrication STT-MRAM device. For example, these channel holes may be close to the plate lines.

Referring to FIG. 5B, an etching process is performed next to selectively etch the middle oxide2 layer 504, to form a recess portion 508 in the middle oxides layer 504. The etching process can be reactive ion etching that is performed using an etchant that is chosen to preferentially remove the oxide material in the middle oxide2 layer 504, but not other layers in the stack structure, including the other oxide1 layers 501 and 507. For each channel hole 500, the etching process may allow to form a recess in each level, thereby removing oxide materials to leave space for forming a TMTJ element at each level of the channel hole.

It is also to be noted that the recess 508 may be formed by removing space around the channel hole 500, and thus each formed recess may be actually a circular structure in each level (or a structure in another different shape depending on the shape of the channel hole). The size of the circular structure (e.g., the radium of each circular structure) may vary and depend on the size of the components (e.g., gate structure among others) included in the TMTJ components.

Referring to FIG. 5C, an insulation layer 510 is then deposited along each formed recess as well as the inner surface of the channel hole 500. According to one embodiment, a high-k dielectric material such as hafnium dioxide (HfO₂), zirconium dioxide (ZrO₂), or titanium dioxide (TiO₂) may be used for this purpose, although other insulation materials such as oxide and nitride can be also used.

Referring to FIG. 5D, a conductive metal layer 512 may be then deposited over the deposited insulation layer 510 as well as the insulator-coated recess. The metal deposited in each recess may be the same as the metal used in the gate electrode for a transistor. For example, the conductive metal can be tungsten (W) and/or tantalum (Ta) or other possible metal materials.

Referring to FIG. 5E, a straight etching process is performed next to remove the coated insulation material and the conductive metal over the inner sidewall of channel hole 500, to form a flattened surface along the inner surface of the channel hole. As can be seen, the insulation material and conductive metal remain inside each recess 514 (which actually is not a recess due to the deposition of the metal) after the straight etching process.

Referring to FIG. 5F, another etching process is further performed to remove a portion of the conductive metal inside each recess, leaving the remaining portion 516 of the conductive metal. Accordingly, another recess 518 is formed through the etching process. The remaining conductive metal 516 may serve as a metal gate electrode (which can be one of the control gate and floating gate) for each transistor.

Referring to FIG. 5G, another depositing process is performed to deposit a polysilicon layer 520 inside each formed recess 518 as well as the inner surface of the channel hole 500. In some embodiments, the polysilicon used for the deposited process may be doped polysilicon.

Referring to FIG. 5H, another straight etching process is further performed to remove the polysilicon deposited over the inner surface of the channel hole 500, to flatten the surface of the channel hole 500. After the straight etching process, polysilicon 520 deposited into the recess in the operation in FIG. 5G remains inside the recess 518 formed in the operation in FIG. 5F, as indicated by portion 522 in FIG. 5H. The polysilicon 522 remaining inside the recess may serve as another gate of the dual gate structure.

Referring to FIG. 5I, an etching process is further performed to selectively remove a portion of each N (nitride) layer and the adjacent P (polysilicon) layer, so as to form two recesses 522a and 522b within each level inside the channel hole 500.

Referring to FIG. 5J, another depositing process is performed to deposit a polysilicon layer 524 within the formed recesses 522a and 522b as well as the inner surface of the channel hole 500. The deposited polysilicon may include non-doped polysilicon that is different from the doped polysilicon used in the formation of the gate structure described above in FIGS. 5G-5H. As can be seen from FIG. 5J, the material used herein may be the same as the material for the layers P used in the beginning depositing process for forming the (O/P/N/O/N/P/O)ₙ.

Referring to FIG. 5K, another etching process is performed to remove the polysilicon formed over the inner surface of each channel hole. In addition, the etching process also removes a portion of polysilicon between a high-k insulation layer and a dielectric oxide layer, thereby forming two recesses 526a and 526b. It can be seen that the etching process does not remove all polysilicon between a high-k insulation layer and a dielectric oxide layer, but rather leaves a portion of polysilicon. The remaining portion of polysilicon in recess 526a or 526b may establish an electrical connection between a word line layer and the dual gate structure.

Referring to FIG. 5L, an oxide layer 528 is then deposited to fill each recess 526a or 526b. The deposition process may also cover the top of the insulation layer and the doped polysilicon filled within the recess formed earlier. The oxide material used in the deposition process may be the same as (or different from) the oxide1 layer 501 or 507 adjacent to a word line.

Referring FIG. 5M, a straight etching process is then performed to remove the oxide layer over the surface of the insulation layer 530.

Referring to FIG. 5N, an etching process is further performed to remove a top portion of the insulation layer 530 and the corresponding doped polysilicon portion. The depth of the formed recess 532 may correspond to the thickness of the magnetic free layer of the MTJ included in the TMTJ element.

Referring to FIG. 5O, a deposition process is performed to deposit a magnetic material inside each formed recess to form a magnetic free layer 534. The magnetic material for forming the magnetic free layer 534 may be CoFeB, Fe, Co, Ni, or alloys thereof. At this moment, the components specific to a TMTJ are all formed. The following processes mainly relate to the formation of the shared non-magnetic tunnel barrier layer and the core as well as other structures included in the in-fabrication STT-MRAM device.

Referring to FIG. 5P, a non-magnetic tunnel barrier layer 536 is deposited inside the inner surface of the channel hole 500. The non-magnetic tunnel barrier layer 536 is formed across the whole inner surface of the channel hole 500 and thus covers the previously formed magnetic free layer 534. The non-magnetic tunnel barrier layer 536 can be any non-magnetic material, such as Ru, Ta, TaN, Cu, CuN, MgO, etc.

Referring to FIG. 5Q, a magnetic reference layer 538 is further formed over the non-magnetic tunnel barrier layer 536. Similar to the non-magnetic tunnel barrier layer 536, the magnetic reference layer 538 also covers all inner surface of the channel hole 500, and thus is a shared layer among TMTJs across all levels of channel hole 500. The magnetic reference layer 538 can be made of Ta, W, Mo, Hf, etc.

Referring to FIG. 5R, a metal layer 540 is further formed over the magnetic reference layer 538. The metal layer 540 can be made with W or another different metal material. In some embodiments, the metal layer 540 may fill the remaining space of each channel hole after forming the magnetic reference layer 538. That is, the core of each channel hole is made of a metal such as W. The metal layer 540 may serve as a bit line layer for connecting to a bit line for the TMTJs formed within each channel hole.

In some embodiments, the metal layer 540 does not fill the remaining space of each channel hole after forming the magnetic reference layer 538. At this point, an additional deposition process may be performed to deposit a dielectric material core 542 to fill the remaining space of the channel hole 500 after forming the metal layer 540. The dielectric core 542 can be made of oxide or another dielectric material and can serve as a support structure of the formed channel hole, which may be also referred to as “channel structure” at this point after the channel hole is completely filled.

At this time point, the in-fabrication STT-MRAM device includes the essential TMTJ elements that are stacked over one another to form stacked TMTJs. FIG. 5S illustrates an exemplary in-fabrication STT-MRAM device that includes a set of channel structures 50 and a plurality of levels of formed TMTJs 52. It is to be noted that only a portion of the in-fabrication STT-MRAM device in the cell array region is illustrated in FIG. 5S. The staircase structure region that does not include channel structures is not shown in the illustrated structure in FIG. 5S.

FIG. 5T illustrates an in-fabrication STT-MRAM device that includes a cell array region 30 and a staircase structure region 40 (although the staircase structure is not formed yet) that does not include the channel structures as shown in the cell array region.

FIG. 5U illustrates an in-fabrication STT-MRAM device with a staircase structure region 40 that includes a staircase structure 54 formed in the staircase structure region 40. In some embodiments, the staircase structure 54 is formed by performing a plurality of so-called “trim-etch” cycles to each level of (O/P/N/O/N/P/O)₁ toward the substrate. Due to the repeated trim-etch cycles applied to each level of (O/P/N/O/N/P/O)₁, each level of (O/P/N/O/N/P/O)₁ can have one or more tilted edges, as illustrated in FIG. 5U. In some embodiments, each trim-tech cycle includes two trim etching processes that each apply to one of the two word line layers in each level, as also illustrated in FIG. 5U.

Referring to FIG. 5V, in some embodiments, a dielectric layer 550 is further deposited to cover the formed staircase structure region 54. A set of word line contact plugs 552 are then formed in the staircase structure region 40. Each word line contact plug 552 extends vertically through the dielectric layer 550, and an end of a word line contact plug lands on a word line layer, such that each word line contact plug is electrically connected to a corresponding word line layer. Each word line contact plug may be electrically connected to a corresponding word line layer to individually address the corresponding word line of a TMTJ.

Although not shown, in some embodiments, a word line contact plug 552 is formed by first forming a vertical opening through the dielectric layer 550 using a wet/dry etching process, followed by filling the opening with conductor materials and other possible materials (e.g., materials to form a barrier layer, an adhesion layer, and/or a seed layer) for conductor filling, adhesion, and/or other purposes. The conductor materials in the word line contact plugs 552 may include, but are not limited to, W, Co, Cu, Al, doped silicon, silicides, or any combination thereof. The openings for forming the word line contact plugs may be filled using Atomic Layer Deposition (ALD), Chemical Vapor Deposition (CVD), Physical Vapor Deposition (PVD), electroplating, any other suitable processes, or any combination thereof.

In some embodiments, a set of contact pads 554 are further formed over the formed word line contact plugs 552. The contact pads 554 may include conductor materials including, but not limited to, W, Co, Cu, Al, doped silicon, silicides, or any combination thereof.

Referring to FIG. 5W, in some embodiments, a set of plate lines (or plate line structures) 560 can be also formed in the cell array region 30. The plate line structures 560 may be formed by first etching the stack structure in the cell array region 30, to form a plurality of vertically aligned trenches, and then filling the trenches with conductive materials including, but not limited to, W, Co, Cu, Al, doped silicon, silicides, or any combination thereof.

In some embodiments, to prevent the formed plate line structures from connecting with word line layers or the drain layer associated with the transistors, a recess may be first formed in each word line layer or drain layer after forming the vertically aligned trenches. Each formed recess is then filled with a dielectric material before filling the trenches with conductive materials. This then prevents the formed plate line structures 560 from connecting with the word line layers and drain layers. In some embodiments, the formed trenches or plate line structures may extend continuously (e.g., plate line structure 560a in FIG. 5W) or discretely (e.g., plate line structure 560b in FIG. 5W). In some embodiments, the plate line structures are formed before forming the staircase structure. In some embodiments, the plate line structures are formed after forming the staircase structure.

In some embodiments, additional essential components, such as bit lines, are further added to the as-formed 3D STT-MRAM device, thereby forming a 3D STT-MRAM device with multiple levels of stacked TMTJ elements with a high density of MTJ memory cells.

The above-detailed descriptions only illustrate certain exemplary embodiments of the present disclosure and are not intended to limit the scope of the present disclosure. Those skilled in the art may understand the specification as a whole and technical features in the various embodiments may be combined into other embodiments understandable to those persons of ordinary skill in the art. Any equivalent or modification thereof, without departing from the spirit and principle of the present disclosure, falls within the true scope of the present disclosure.

What is claimed is:

1. A memory device, comprising:
a semiconductor layer;
a stack structure over the semiconductor layer, the stack structure including a cell array region, wherein
the cell array region includes multiple vertical levels of stacked transistor-magnetic tunnel junction (TMTJ) elements and a plurality of channel structures vertically extending through the stack structure; and
at least one channel structure includes a vertical core, a vertical magnetic reference layer, and a vertical tunnel barrier layer, which are shared by a set of magnetic tunnel junction (MTJ) elements associated with the at least one channel structure, the set of MTJ elements located at different vertical levels of the stack structure.

2. The memory device of claim 1, wherein an MTJ element included in the set of MTJ elements includes an individual vertical magnetic free layer that is not shared with another MTJ element included in the set of MTJ elements.

3. The memory device of claim 1, wherein the at least one channel structure further includes a vertical word line layer shared by the set of MTJ elements.

4. The memory device of claim 3, wherein the vertical word line layer, the vertical magnetic reference layer, and the vertical tunnel barrier layer are arranged according to an order from the core towards an edge of the at least one channel structure.

5. The memory device of claim 1, wherein a TMTJ element further includes one or more vertical gate electrodes adjacent to a vertical magnetic free layer of the TMTJ element.

6. The memory device of claim 5, wherein the TMTJ element further includes one or more word line layers associated with the one or more gate electrodes, wherein the one or more word line layers laterally extend towards a staircase structure region included in the stack structure.

7. The memory device of claim 6, wherein the staircase structure region further includes one or more contact plugs associated with the one or more word line layers.

8. The memory device of claim 7, wherein the one or more contact plugs include two contact plugs associated with two word lines for a single TMTJ element.

9. The memory device of claim 1, wherein the cell array region further includes one or more vertical plate line structures that extend along a lateral direction.

10. The memory device of claim 9, wherein a TMTJ element further includes a source line layer connected to one of the one or more vertical plate line structures.

11. The memory device of claim 1, wherein the vertical core comprises a bit line layer that serves as a bit line for the set of MTJ elements.

12. The memory device of claim 1, wherein the vertical core, the vertical magnetic reference layer, and the vertical tunnel barrier layer have a same shape of a circle, an eclipse, or a rectangular.

13. A method of forming a memory device, comprising:
forming a vertical stack structure over a semiconductor layer, the stack structure including a plurality of levels, each level including a plurality of vertically aligned horizontal layers;
forming at least one channel structure within the stack structure, each of the at least one channel structure including a vertical core, a vertical magnetic reference layer, and a vertical tunnel barrier layer; and
within each level, forming a vertical magnetic free layer coupled to each of the at least one channel structure, and forming a transistor adjacent to the vertical magnetic free layer, wherein the vertical magnetic free layer, a portion of the vertical magnetic reference layer in the level, and a portion of the vertical tunnel barrier layer in the level together form a magnetic tunnel junction (MTJ) element, and the MTJ element and the adjacent transistor together form a TMTJ element.

14. The method of claim 13, wherein the plurality of vertically aligned horizontal layers in each level include a first dielectric layer, a first conductor layer, a second dielectric layer, a third dielectric layer, a fourth dielectric layer, a second conductor layer, and a fifth dielectric layer that are vertically aligned from a top towards the semiconductor layer.

15. The method of claim 14, where, in each level, a TMTJ element associated with each of the at least one channel structure is formed by:
forming a channel hole vertically extending through the stack structure; and
in each level,
forming a recess surrounding the channel hole, the recess being formed in the third dielectric layer;
forming an insulation layer surrounding the recess;
forming one or more gate electrodes within the recess; and
forming a vertical magnetic free layer adjacent to the one or more gate electrodes, a surface of the vertical magnetic free layer being in-plane with an inner wall of the channel hole.

16. The method of claim 15, wherein forming the one or more gate electrodes comprises:
forming a first gate electrode adjacent to a vertical inner surface of the recess, the first gate electrode including a metal material; and
forming a second gate electrode adjacent to the first gate electrode, the second gate electrode including a doped polysilicon material.

17. The method of claim 15, where, before forming the vertical magnetic free layer, the method further comprises:
forming a first recess within the first conductor layer and the first nitride layer and a second recess within the second conductor layer and the second nitride layer;
depositing a conductive material within the first recess and the second recess;
performing a straight etching process;
forming a third recess by removing a portion of the conductive material deposited within the first recess and forming a fourth recess by removing a portion of the conductive material deposited within the second recess; and
filling in the third recess and the fourth recess with a dielectric material.

18. The method of claim 14, further comprising forming one or more plate line structures within the stack structure, the one or more plate line structures connected to one or more second dielectric layers.

19. The method of claim 14, further comprising forming one or more staircase structures within the stack structure, wherein a staircase structure includes a plurality of contact plugs associated with first conductor layers and second conductor layers in different levels.

20. The method of claim 19, wherein, in each level, a stair length associated with the first conductor layer is shorter than a stair length associated with the second conductor layer.
